(19) United States
(12) Patent Application Publication
(10) Pub. No.: US 2018/0170800 A1
(43) Pub. Date: Jun. 21, 2018

(54) LAMINATED BODY

(71) Applicant: Asahi Glass Company, Limited, Chiyoda-ku (JP)

(72) Inventors: Misa INAMOTO, Chiyoda-ku (JP); Naoki OKAHATA, Chiyoda-ku (JP); Yuki AOSHIMA, Chiyoda-ku (JP)

(73) Assignee: Asahi Glass Company, Limited, Chiyoda-ku (JP)

(21) Appl. No.: 15/891,482

(22) Filed: Feb. 8, 2018

Related U.S. Application Data
(63) Continuation of application No. PCT/JP2016/069347, filed on Jun. 29, 2016.

(30) Foreign Application Priority Data
Aug. 19, 2015 (JP) 2015-162300

(51) Int. Cl. C03C 15/00; C23C 14/30; C23C 14/10; C23C 14/08; C23C 14/02; C03C 17/30; C03C 17/42; C03C 21/00; C23C 14/00; C23C 14/34

(52) U.S. Cl. CPC C03C 15/00; C03C 2218/31; C23C 14/10; C23C 14/083; C23C 14/021; C03C 17/30; C03C 17/42; C03C 21/002; C23C 14/0036; C23C 14/34; C23C 14/3464; C03C 2217/78; C03C 2218/11; C03C 2218/155; C03C 2218/151; C23C 14/30

(57) ABSTRACT

A laminated body includes a substrate provided with a first surface; a rugged layer including fluorine; and an antifouling layer. The rugged layer has an average surface roughness of 0.05-50 nm. A peak of a binding energy of F1s in the rugged layer falls within 684-687.5 eV, a ratio of atomic concentrations of fluorine to silicon obtained from peaks of binding energies of F1s and Si2p falls within 0.003-100. A peak of a binding energy of F1s in the antifouling layer falls within 687.5-691 eV. An F-value, (A−B)/(C−B), is 0.1 or more, where “A” is an F-Kα line strength of the laminated body measured from the antifouling layer side by a fluorescent X-ray measurement device, “B” is an F-Kα line strength of a glass plate with only trace amounts of fluorine, and “C” is an F-Kα line strength of an aluminosilicate glass plate including fluorine of 2 wt %.

### CROSS-REFERENCE TO RELATED APPLICATION

The present application is a continuation application filed under 35 U.S.C. 111(a) claiming benefit under 35 U.S.C. 120 and 365(c) of PCT International Application No. PCT/JP2016/069347 filed on Jun. 29, 2016 and designating the U.S., which claims priority of Japanese Patent Application No. 2015-162300 filed on Aug. 19, 2015. The entire contents of the foregoing applications are incorporated herein by reference.

### BACKGROUND OF THE INVENTION

### 1. Field of the Invention

The disclosure herein generally relates to a laminated body.

### 2. Description of the Related Art

Conventionally, for example, a laminated body obtained by arranging an antifouling layer on a substrate has been used in a wide range of areas, such as a cover plate of an apparatus including a touch panel type display unit.

Typically, in a laminated body for such a cover plate, a glass substrate has been used for the substrate, and a fluorine-based compound has been used in the antifouling layer (See, for example, WO 2014/61615).

### SUMMARY OF THE INVENTION

### Technical Problem

However, such a laminated body is, in an actual usage environment, subjected to an operation of rubbing with a finger, or an operation of rubbing a smear on a surface away with a cloth. In the case where such an operation to the laminated body is repeated, the antifouling layer is gradually deteriorated or exfoliated, and finally, appropriate antifouling function may be lost. Accordingly, a laminated body having an antifouling layer that exhibits an excellent durability under an actual usage environment has been required.

The present invention was made in view of such a background, and it is an object of the present invention to provide a laminated body having an antifouling layer that exhibits more excellent durability than the related art.

### Solution to Problem

According to an aspect of the present invention, a laminated body including, in this order,

a substrate having a first surface;

a rugged layer including fluorine; and

an antifouling layer,

the rugged layer having an arithmetic average surface roughness Ra that falls within a range from 0.05 nm to 50 nm,

a peak of a binding energy of F1s of fluorine in the rugged layer falling within a range of greater than or equal to 684 eV and less than or equal to 687.5 eV, a ratio of an atomic concentration (atm %) of fluorine obtained from the peak of the binding energy of F1s of fluorine to an atomic concentration (atom %) of silicon obtained from a peak of a binding energy of Si2p of silicon, F1s/Si2p, falling within a range from 0.003 to 100,

a peak of a binding energy of F1s of fluorine in the antifouling layer falling within a range of greater than 687.5 eV and less than or equal to 691 eV, and

an F-value expressed by the following formula (1):

F-value=(A−B)/(C−B), formula (1)

being greater than or equal to 0.1, is provided.

In the formula (1), “A” is an F-Kα line strength of the laminated body measured from the antifouling layer side by a fluorescent X-ray measurement device, “B” is an F-Kα line strength of a glass plate that practically does not include fluorine measured by the fluorescent X-ray measurement device, and “C” is an F-Kα line strength of an aluminosilicate glass plate including fluorine of 2 wt % measured by the fluorescent X-ray measurement device.

### Advantageous Effect of Invention

According to an aspect of the present invention, a laminated body including an antifouling layer that exhibits more excellent durability than the related art can be provided.

### BRIEF DESCRIPTION OF THE DRAWINGS

Other objects and further features of embodiments will become apparent from the following detailed description when read in conjunction with the accompanying drawings, in which:

FIG. 1 is a diagram schematically depicting an example of a cross section of a laminated body according to an embodiment of the present invention;

FIG. 2 is a flowchart schematically depicting an example of a manufacturing method of the laminated body illustrated in FIG. 1;

FIG. 3 is a diagram schematically depicting an example of an apparatus that is used when forming a rugged layer on a first surface of a glass substrate;

FIG. 4 is a diagram schematically depicting another example of the cross section of the laminated body according to the embodiment of the present invention;

FIG. 5 is a flowchart schematically depicting an example of a manufacturing method of the laminated body illustrated in FIG. 4;

FIG. 6 is a diagram schematically depicting yet another example of the cross section of the laminated body according to the embodiment of the present invention; and

FIG. 7 is a flowchart schematically depicting an example of a manufacturing method of the laminated body illustrated in FIG. 6.

### DETAILED DESCRIPTION OF THE PREFERRED EMBODIMENTS

In the following, with reference to drawings, embodiments of the present invention will be described.

### First Embodiment

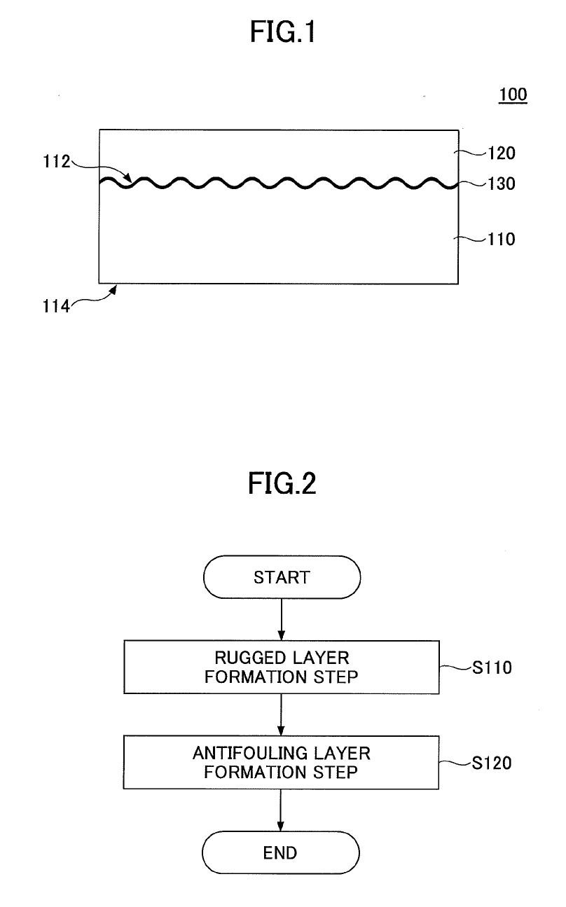

With reference to FIG. 1, a first embodiment of the present invention will be described. FIG. 1 schematically illustrates a cross section of a laminated body according to the embodiment of the present invention (in the following, referred to as a “first laminated body”).

As illustrated in FIG. 1, the first laminated body 100 includes a substrate 110, and an antifouling layer 120. The substrate 110 has a first surface 112 and a second surface 114. The antifouling layer 120 is arranged on the first surface 112 side.

The substrate 110 is configured of a material including silicon (Si). The substrate 110 is, for example, configured of a transparent or translucent glass substrate, a resin substrate or the like.

The antifouling layer 120 is configured of a material including fluorine (F). Moreover, the antifouling layer 120 has an “antifouling function”, i.e. the antifouling layer 120 is used for preventing a smear such as a fingerprint, a fat, and/or the like from adhering on the first laminated body 100, or for facilitating removing such a smear.

The first laminated body 100, described as above, can be used for a cover plate of an apparatus having a touch panel type display unit, such as a smartphone, a tablet type mobile information terminal, or a tablet type personal computer.

The first laminated body 100 includes a rugged layer 130 including fluorine (F) on the first surface 112 of the substrate 110. In other words, in the first laminated body 100, the rugged layer 130 including fluorine (F) is arranged between the substrate 110 and the antifouling layer 120.

Note that in the specification of the present application, the “rugged layer including fluorine” means a “fine” rugged structure part including fluorine formed on a surface of a bulk body (e.g. a substrate, a layer, or a film). In addition, the term “fine” means that the surface roughness Ra (arithmetic average roughness Ra stipulated by Japanese Industrial Standards (JIS B0601), the same applies to the following) falls within a range of 0.5 nm to 50 nm.

The “rugged layer including fluorine” may be, for example, arranged continuously on a surface of the bulk body, or may be arranged locally (intermittently). FIG. 1 is a diagram schematically illustrating the rugged layer including fluorine arranged continuously.

Note that in the following description, the “rugged layer including fluorine” may be simply referred to as a “rugged layer”.

In the first laminated body 100, the surface roughness Ra of the rugged layer 130 falls within a range of 0.5 nm to 50 nm. Moreover, a peak of a binding energy of F1s of fluorine in the rugged layer 130 falls within a range of 684 eV or more and 687.5 eV or less. A ratio of an atomic concentration (atom %) of fluorine obtained from the peak of the binding energy of F1s of fluorine to an atomic concentration (atom %) of silicon obtained from a peak of a binding energy of Si2p of silicon, i.e. F1s/Si2p, falls within a range of 0.003 to 100. The inventors of the present invention have found, by investigation, that when the surface roughness Ra increased beyond 30 nm, a tendency of being rough to the feel for some people began to appear.

Note that peaks of binding energies of F1s of fluorine and Si2p of silicon in the rugged layer 130 can be measured by using an X-ray photoelectric spectroscopy measurement apparatus.

Furthermore, in the first laminated body 100, the peak of the binding energy of F1s of fluorine measured on the antifouling layer 120 side falls within a range of greater than 687.5 eV and less than or equal to 691 eV. Moreover, in the antifouling layer, an F-value expressed by the following formula (1)

F-value=(A−B)/(C−B) formula (1)

is 0.1 or more.

In the formula (1), “A” is an F-Kα line strength of the first laminated body 100 measured from the antifouling layer 120 side by a fluorescent X-ray measurement device, “B” is an F-Kα line strength of a glass plate that practically does not include fluorine measured by the fluorescent X-ray measurement device, and “C” is an F-Kα line strength of an aluminosilicate glass plate including fluorine of 2 wt % measured by the fluorescent X-ray measurement device.

The inventors of the present application have found that in the case of combining the rugged layer 130 and the antifouling layer 120, each having the aforementioned feature, and applying to the laminated body, the durability of the laminated body in an actual usage environment was significantly improved. Results will be described in detail later.

Such a laminated body has an effect that more of a fluorine based compound is deposited as the antifouling layer than a case of a typical flat base material (Ra is less than or equal to 0.2). That is, when the same amount of raw material is used, an amount of compound that is actually vapor-deposited is greater. The aforementioned affect that the initial F-value is greater is considered to be one of the main reasons that the durability is improved. When the typical flat base material is used, the amount of compound that is actually vapor-deposited is limited. Even if the amount of raw material is increased, the raw material is liable to aggregate to be a haze without coupling to the base material. Such an aggregate tends to be eliminated in a post processing in the deposition process, i.e. in a finishing processing such as cleansing, wiping, or attaching/peeling of film. Although the detailed reason why more of the antifouling layer is deposited on the laminated body has not been found at present, as one factor, it is considered that an area of an uppermost surface is increased because the rugged layer 130 existing on a substrate side with respect to the antifouling layer 120 has an appropriate surface roughness Ra (Ra falls within a range from 0.3 nm to 30 nm).

As another reason why the durability is improved, it is considered that an adhesiveness of the antifouling layer 120 to the substrate 110 is improved, because the laminated body has a rugged layer with an appropriate surface roughness Ra (Ra is 0.3 nm to 30 nm), an area of coupling between the laminated body and the antifouling layer is increased, and more couplings are promoted. In a technique of increasing the adhesiveness between a coating layer and the substrate according to the “anchor effect” that is typical in the field of coating, i.e. an adhesiveness improvement effect which appears when a coating layer is embedded into a surface of a roughened substrate, the surface roughness Ra of the surface of the substrate becomes at least an order of a few μm. Compared with the surface roughness Ra used for the anchor effect, described as above, the surface roughness Ra of the rugged layer 130 in the first laminated body 100 is on an order of nanometers, and is quite small. Then, the effect of the surface roughness Ra of the rugged layer 130 can be a new effect that is different from the effect of improving the adhesiveness according to the conventional anchor effect.

In the first laminated body 100 having the rugged layer 130 and the antifouling layer 120 with the aforementioned feature, even when the laminated body 100 is used repeatedly in the mode of rubbing with a finger or rubbing a smear on a surface away with a cloth, the antifouling layer is not liable to be degraded or exfoliated. Moreover, because the initial amount of fluorine based compound configuring the antifouling layer 120 is great, even if a part of the antifouling layer is degraded or exfoliated, the effect can be maintained for a long period. Thus, the aforementioned antifouling function of the antifouling layer 120 can be fulfilled stably, and the first laminated body 100 that exhibits an excellent durability can be provided.

(Respective Members Configuring First Laminated Body 100)

Next, the respective members configuring the first laminated body 100 with the configuration illustrated in FIG. 1 will be described in detail. Note that in order to make clear the explanation, when illustrating the respective members, the reference numerals used in FIG. 1 will be used.

(Substrate 110)

A thickness of the substrate 110 is preferably 3 mm or less, and may fall within a range of 0.2 mm to 2 mm, for example. The thickness of the substrate 110 more preferably falls within a range of 0.3 mm to 1.5 mm. When the thickness of the substrate 110 is 3 mm or more, a weight of the substrate 110 increases and it becomes difficult to reduce the weight of the first laminated body 100. Moreover, a cost of a raw material increases.

The substrate 110 preferably has a Martens hardness that falls within a range of 1000 N/mm² to 5000 N/mm², for example. When the Martens hardness is 1000 N/mm² or more, a substrate 110 having durability can be applied. Moreover, when the Martens durability is 5000 N/mm² or less, the substrate can be easily processed, and is preferable. The Martens hardness falls more preferably within a range of 2000 N/mm² to 4500 N/mm².

The substrate 110 may be formed of a transparent or translucent material including silicon (Si), such as a glass or a resin.

In the case where the substrate 110 is formed of a glass, i.e. in the case where the substrate 110 is a glass substrate, the glass substrate may be famed by a floating method, a fusion method, or the like. Moreover, the glass substrate may be formed of a soda lime silicate glass, aluminosilicate glass, an alkali free glass, or the like. Furthermore, the glass substrate may be subjected to a chemically strengthening process.

The glass substrate includes, for example, SiO₂ of 61 mol % to 77% mol %, Al₂O₃ of 1 mol % to 18 mol %, Na₂O of 0 to 18 mol %, K₂O of 0 to 6 mol %, MgO of 0 to 15 mol %, B₂O₃ of 0 to 8 mol %, Cao of 0 to 9 mol %, SrO of 0 to 1 mol %, BaO of 0 to 1 mol %, and ZrO₂ of 0 to 4 mol %.

(Rugged Layer 130)

The rugged layer 130 includes fluorine, as described above, and has a surface roughness Ra that falls within a range of 0.5 nm to 50 nm. The surface roughness Ra preferably falls within a range of 1 nm to 50 nm, more preferably within a range of 1 nm to 30 nm, further preferably within a range of 4 nm to 30 nm, and the most preferably within a range of 11 nm to 30 nm. When the surface roughness Ra in the rugged layer 130 falls within the aforementioned range, more appropriate adhesiveness can be obtained between the antifouling layer 120 and the substrate 110.

A thickness of the rugged layer 130, at a part of the greatest thickness, falls within a range of 1 nm to 200 nm, for example.

As described above, in the rugged layer 130, the peak of the binding energy of F1s of fluorine measured by using an X-ray photoelectric spectroscopy measurement apparatus falls within a range of 684 eV or more and 687.5 eV or less. A ratio of an atomic concentration (atom %) of fluorine obtained from the peak of the binding energy of F1s of fluorine to an atomic concentration (atom %) of silicon obtained from the peak of the binding energy of Si2p of silicon, i.e. F1s/Si2p, falls within a range of 0.003 to 100. The respective energy peaks were normalized with the peak of carbon contamination C1s, generated by an atmospheric exposure, that was 284.5 eV.

Note that, as illustrated in FIG. 1, the rugged layer 130 is arranged above the substrate 110. The rugged layer 130 may be the first surface 112 of the substrate 110 itself. That is, the rugged layer 130 may be formed by fabricating and/or processing the first surface 112 of the substrate 110.

The rugged layer 130 can be formed, for example, by etching a surface of a glass substrate including Si at a temperature that falls within a range of 300° C. to 800° C., using a hydrogen fluoride gas (HF), a trifluoroacetic acid gas (TFA), or the like.

(Antifouling Layer 120)

The antifouling layer 120 is configured of a material (e.g. a resin) including fluorine. Moreover, the antifouling layer 120 is selected, as described above, so that the peak of the binding energy of F1s of fluorine falls within a range of greater than 687.5 eV and less than or equal to 691 eV.

Moreover, in the antifouling layer 120, an F-value defined by the following formula (1):

F-value=(A−B)/(C−B) formula (1)

is greater than or equal to 0.1.

In the formula (1), “A” is an F-Kα line strength of the first laminated body 100 measured from the antifouling layer 120 side by a fluorescent X-ray measurement device, “B” is an F-Kα line strength of a glass plate that practically does not include fluorine measured by the fluorescent X-ray measurement device, and “C” is an F-Kα line strength of an aluminosilicate glass plate including fluorine of 2 wt % measured by the fluorescent X-ray measurement device.

Note that, the “glass plate that practically does not include fluorine” means a glass plate in which a contained amount of fluorine measured by a secondary ion mass spectrometry (SIMS) is less than 100 ppm. The “glass plate that practically does not include fluorine” may be, for example, a commercially available soda lime glass.

As indicated in formula (1), by subtracting “C” from “A” and “B”, respectively, a zero-point correction for the fluorescent X-ray measurement device can be performed. Moreover, by dividing a value of (A−B) by a value of (C−B), an amount of fluorine included in the antifouling layer 120 can be evaluated with normalization.

The material of the antifouling layer 120 includes, for example, a compound expressed by the following formula (2):

[Chemical 1]

F(CF₂CF₂CF₂Oₖ-L₁-SiL₀)₃ formula (2)

Note that L₁ is a molecular structure formed of C, H, O, N, F or the like, and having an ether linkage, an amide linkage or the like. An integer “k” is a number of repetition, and a natural number of 1 or more and 1000 or less. Furthermore, L₀ is a hydrolysable group that can be exchanged with a terminal OH group of a glass.

The group L₀ is preferably a halogen other than fluorine or an alkoxy group (—OR), where “R” is a linear-chain hydrocarbon or a branched-chain hydrocarbon with one to six carbon atoms, including hydrocarbons of, for example, —CH₃, —C₂H₅, or —CH(CH₃)₂. The halogen is preferably chlorine. The alkoxy silane is preferably tri methoxy silane, Si(OMe)₃.

The antifouling layer 120 may be configured of, for example, the compound expressed by the following formula (3):

[Chemical 2]

CF₃OCF₂OₘCF₂CF₂OₙL₂-SiL₀)₃ formula (3)

Note that L₂ is a molecular structure formed of C, H, O, N, F or the like, and having an ether linkage, an amide linkage or the like. Integers “m” and “n” are numbers of repetition, and natural numbers of 1 or more and 1000 or less, respectively. Furthermore, L₀ is the same as L₀ in the formula (2).

A material of the antifouling layer 120 is not particularly limited, but is preferably a compound having a molecular weight of 100 or more and including fluorine. For the material, for example, S600 (trade name, by Asahi Glass Company, Limited), S550 (trade name, by Asahi Glass Company, Limited), KY-178 (trade name, by Shin-Etsu Chemical Company, Limited), KY-185 (trade name, by Shin-Etsu Chemical Company, Limited), X-71-186 (trade name, by Shin-Etsu Chemical Company, Limited), X-71-190 (trade name, by Shin-Etsu Chemical Company, Limited), X-195 (trade name, by Shin-Etsu Chemical Company, Limited), or the like is preferably used.

A thickness of the antifouling layer 120 falls within a range of 1 nm to 100 nm, for example.

A surface roughness Ra of the antifouling layer 120 may be equivalent to the surface roughness Ra of the rugged layer 130, or furthermore to the surface roughness Ra of the first surface 112 of the substrate 110.

(Manufacturing Method of First Laminated Body 100)

Next, with reference to FIG. 2, a manufacturing method of the first laminated body 100 having the aforementioned features will be described.

FIG. 2 schematically depicts an example of a flow of the manufacturing method of the first laminated body 100 (in the following, referred to as a “first manufacturing method”). As illustrated in FIG. 2, the first manufacturing method includes:

a rugged layer formation step for forming a rugged layer including fluorine on a substrate (step S110); and

an antifouling layer formation step for forming an antifouling layer on the rugged layer (step S120). In the following, the respective steps will be explained.

Note that in order to make clear the explanation, when illustrating the respective members, the reference numerals used in FIG. 1 will be used.

(Step S110)

Initially, a substrate 110 having a first surface 112 and a second surface 114 is prepared. Moreover, a rugged layer 130 including fluorine is formed on the first surface 112 of the substrate 110. In the following, an example in which the substrate 110 is a glass substrate 110, will be described.

A method for forming the rugged layer 130 including fluorine on the first surface 112 of the substrate 110 is not particularly limited. For example, the rugged layer 130 including fluorine may be formed by etching the first surface 112 of the substrate 110 using an etchant (liquid or gas) including molecules having structures in which fluorine atoms exist.

An etching system may be a dry etching system, a wet etching system, a chemical etching system, a physical etching system, or a combination thereof. A method of the etching is not particularly limited, but, for example, in the case of the dry etching system, any of a CVD method, a plasma CVD method, a reactive ion etching (RIE) method, an inductively couple plasma (ICP) method, a reverse sputtering method, an ion milling method, and a laser ion source (LIS) method, or a combination thereof may be employed. Moreover, in the case of using a liquid, a processing liquid may be supplied to a surface, for example, by spray coating in a state of liquid, or may be supplied to the surface after vaporizing the liquid.

In the following, as an example, a method of forming the rugged layer 130 on a surface of the glass substrate 110 using a chemical etching method will be described.

In this case, a temperature of the glass substrate 110 for the etching process is not particularly limited, but typically an etching process is performed at a temperature that falls within a range of 300° C. to 800° C. The temperature for etching process preferably falls within a range of 400° C. to 700° C., and more preferably a range of 450° C. to 700° C.

An etchant used for preparing the rugged layer 130, i.e. a gas or a liquid including molecules having structures in which fluorine atoms exist includes, for example, hydrogen fluoride (HF), hydrofluoric acid, a fluorine single body, trifluoroacetic acid, carbon tetrafluoride, silicon tetrafluoride, phosphorus pentafluoride, phosphorus trifluoride, boron trifluoride, nitrogen trifluoride, chlorine trifluoride and the like, but is not limited to these gases or liquids. Moreover, the etchant may be diluted with other liquid or gas as necessary. Moreover, two or more kinds of these gases may be mixed to be used.

The etchant may include a liquid or a gas other than the aforementioned liquid or gas. The liquid or gas is not particularly limited, but is preferably a liquid or gas that does not react with a molecule having a structure in which a fluorine atom exists at the room temperature. For example, the liquid or gas includes N₂, air, H₂, O₂, Ne, Xe, CO₂, Ar, He, Kr or the like, but is not limited to these gases. Moreover, two or more kinds of these gases may be mixed to be used. For a carrier gas for the gas having a structure in which a fluorine atom exists, an inactive gas, such as N₂ or argon, is preferably used.

Furthermore, the etchant may include water vapor or water. Moreover, the etchant may include SO₂.

A concentration of a gas or a liquid including molecules having structures in which fluorine atoms exist in the etchant is not particularly limited as long as the rugged layer 130 having the aforementioned feature is formed on a surface of the substrate 110. A concentration of a reaction gas in a processing gas, for example, for hydrogen fluoride falls within a range of 0.1 vol % to 15 vol %, preferably a range of 0.1 vol % to 10 vol %, and more preferably a range of 0.2 vol % to 7 vol %. In such a case, the concentration of hydrogen fluoride gas (vol %) in the processing gas is obtained from a ratio of a flow rate of hydrogen fluoride gas to a sum of the flow rate of hydrogen fluoride, a flow rate of a carrier gas and a flow rate of a dilution gas.

Although the etching process for the glass substrate 110 may be performed in a reaction container, if necessary, e.g. in the case where a size of the glass substrate 110 is great, the etching process for the glass substrate 110 may be performed in the state where the glass substrate 110 is conveyed. In such a case, compared with the process in the reaction container, a rapid and highly efficient process is possible.

(Device for Forming the Rugged Layer 130)

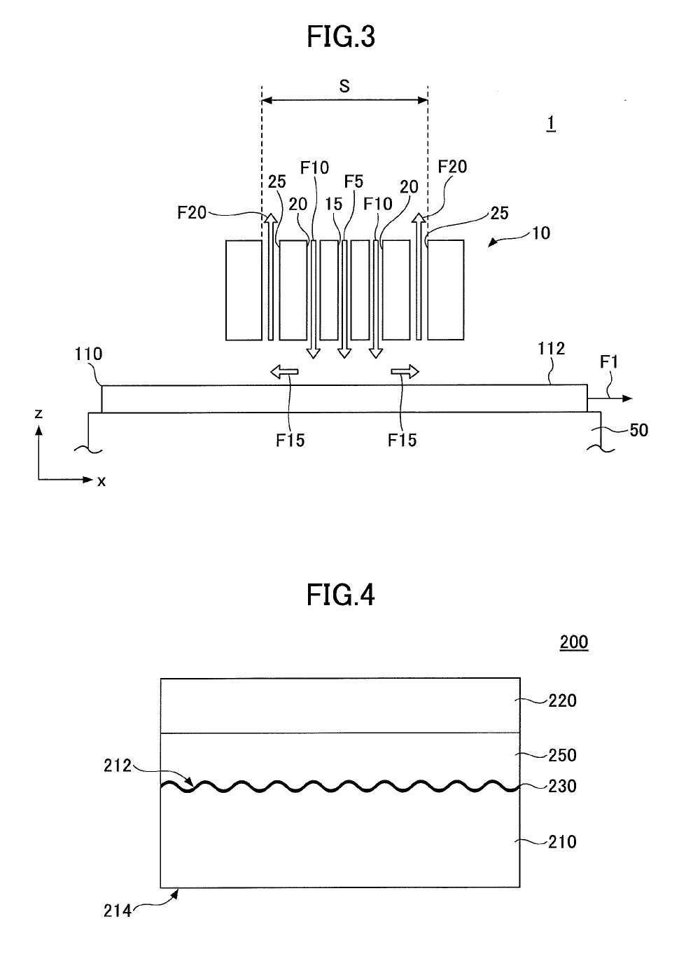

In the following, with reference to FIG. 3, an example of a device that can be used for forming the rugged layer 130 will be briefly described.

FIG. 3 schematically illustrates the device that can be used for forming the rugged layer 130 on the first surface 112 of the glass substrate 110. The device 1 can form the rugged layer 130 on the first surface 112 in the state where the glass substrate 110 is conveyed.

As illustrated in FIG. 3, the device 1 is provided with an injector 10 and a conveying means 50.

The conveying means 50 can convey the glass substrate 110 placed on an upper part in the horizontal direction (x-axis direction), as indicated by an arrow F1.

The injector 10 is arranged above the conveying means 50 and the glass substrate 110.

The injector 10 includes a plurality of slits 15, 20 and 25 that become flow paths for the processing gas. That is, the injector 10 is provided with a first slit 15 arranged in a central portion in a vertical direction (z-axis direction), a second slit 20 arranged in the vertical direction (z-axis direction) so as to surround the first slit 15, and a third slit 25 arranged in the vertical direction (z-axis direction) so as to surround the second slit 20. These slits are not necessarily required to be orthogonal to the conveyance direction of the substrate, and they may be slanted off the conveyance direction.

One end (upper portion) of the first slit 15 is connected to a hydrogen fluoride gas source (not shown) and a carrier gas source (not shown), and another end (lower portion) of the first slip 15 is oriented toward the glass substrate 110. Similarly, one end (upper portion) of the second slit 20 is connected to a dilution gas source (not shown), and another end (lower portion) of the second slit 20 is oriented toward the glass substrate 110. One end (upper portion) of the third slit 25 is connected to an exhaust system (not shown), and another end (lower portion) of the third slit 25 is oriented toward the glass substrate 110.

In the case of forming the rugged layer 130 by using the device 1 that is configured in this way, initially, a hydrogen fluoride gas is supplied from the hydrogen fluoride gas source (not shown) in the direction indicated by an arrow F5 via the first slit 15. Moreover, a dilution gas, such as nitrogen, is supplied from the dilution gas source (not shown) in the direction indicated by an arrow F10 via the second slit 20. These gasses are, by the exhaust system, moved in the horizontal direction (x-axis direction) along an arrow 15, and then exhausted to the outside of the device 1 via the third slit 25.

Note that to the first slit 15, in addition to the hydrogen fluoride gas, the carrier gas such as nitrogen may be supplied simultaneously.

Next, the conveying means 50 is operated. Then, the glass substrate 110 moves in the direction indicated by the arrow F1.

The glass substrate 110 contacts the processing gas, including the hydrogen fluoride gas, the carrier gas and the dilution gas, supplied from the first slit 15 and the second slit 20. Then, the first surface 112 of the glass substrate 110 is subjected to the etching process, and the rugged layer 130 is formed.

The processing gas supplied on an upper surface of the glass substrate 110 moves in the direction indicated by the arrow F15 and is used for the etching process. Afterwards, the processing gas moves in the direction indicated by an arrow F20 and is exhausted to the outside of the device 1 via the third slit 25 connected to the exhaust system.

By using the aforementioned device 1, the rugged layer 130 can be formed while conveying the glass substrate 110. In this case, compared with the case of forming the rugged layer 130 using the reaction container, processing efficiency can be enhanced. Moreover, in the case of using the aforementioned device 1, it is also possible to form a rugged layer 130 also on a glass substrate 110 with a great size.

A supply speed of the processing gas to the glass substrate 110 is not particularly limited. The supply speed of the processing gas may fall within a range of 0.1 SLM to 1000 SLM, for example. The unit SLM is an abbreviation of Standard Liter per Minute (flow rate in the standard state). Moreover, a transit time of the injector 10 of the glass substrate 110 (time required to pass a distance “S” in FIG. 3) falls within a range of 1 second to 120 seconds, preferably a range of 2 seconds to 60 seconds, and more preferably a range of 3 seconds to 30 seconds. When the transit time of the injector 10 of the glass substrate 110 is 320 seconds or less, the rugged layer 130 can be formed rapidly. In the following, the transit time of the injector 10 of the glass substrate 110 will also be referred to as an “etching process time”.

In this way, by using the device 1, the rugged layer 130 can be formed on the glass substrate in the state of conveyance.

Note that the device 1 illustrated in FIG. 3 is merely an example, and the rugged layer 130 may be formed by using a device other than the device 1.

For example, in the device illustrated in FIG. 3, the glass substrate 110 moves relatively to the injector 10 at rest. However, contrary to this operation, the injector may move in the horizontal direction with respect to the glass substrate 110 at rest. Alternatively, both the glass substrate 110 and the injector 10 may move in the opposite directions to each other. Moreover, the injector may be arranged below the conveying means 50 and the glass substrate 110 to form the rugged layer 130 on the lower surface of the glass substrate 110.

Moreover, the device 1 illustrated in FIG. 3 includes three slits 15, 20 and 25, in total. However, the number of slits is not particularly limited. For example, the number of slots may be two. In this case, one slit may be used for supplying the processing gas (mixed gas of the carrier gas, the hydrogen fluoride gas and the dilution gas), and another slit may be used for exhausting gas. Moreover, one or more slits may be arranged between the slit 20 and the exhaust slit 25, and may be caused to supply the etching gas, the carrier gas and/or the dilution gas.

Furthermore, in the device 1 illustrated in FIG. 3, the second slit 20 of the injector 10 is arranged so as to surround the first slit 15, and the third slit 25 is arranged so as to surround the first slit 15 and the second slit 20. However, instead of the aforementioned arrangement, the first slit, the second slit and the third slit may be arrayed in line in the horizontal direction (x-axis direction). In this case, the processing gas moves in one direction on the upper surface of the glass substrate, and afterwards, the processing gas is exhausted via the third slit.

Furthermore, a plurality of injectors 10 may be arranged above the conveying means 50 in the horizontal direction (x-axis direction).

(Chemically Strengthening Process)

According to the aforementioned processes, the rugged layer 130 including fluorine was formed on the first surface 112 of the glass substrate 110.

Note that, if necessary, afterwards, the glass substrate 110 may be subjected to the chemically strengthening process.

The “chemical strengthening process (method)” collectively means a technique of immersing a glass substrate into a molten salt including alkali metal to replace alkali metal (ions) with a small atomic diameter existing on the outeLmost surface of the glass substrate by alkali metal (ions) with a great atomic diameter existing in the molten salt. According to the “chemical strengthening process (method)”, on a surface of the processed glass substrate, alkali metal (ions) with a greater atomic diameter than the atoms before the chemical strengthening process is arranged. Thus, a compressive stress layer can be formed on a surface of the glass substrate, and the strength of the glass substrate is improved.

For example, when the glass substrate includes sodium (Na), at the time of the chemical strengthening process in molten-salt (e.g. nitrate salt), sodium is replaced by, for example, potassium (K). Alternatively, when the glass substrate includes, for example, lithium (Li), at the time of the chemical strengthening process, lithium may be replaced in the molten-salt (e.g. nitrate salt) by, for example, sodium (Na) and/or potassium (K).

Conditions for the chemically strengthening process performed for a glass substrate are not particularly limited.

The molten salt includes, for example, alkali metal nitrate, alkali metal sulfate, alkali metal chloride, carbonate, perchlorate or the like, such as sodium nitrate, potassium nitrate, sodium sulfate, potassium sulfate, sodium chloride, or potassium chloride. The aforementioned molten salt may be used alone, or a plurality of types of molten salts may be combined for use.

A process temperature (temperature of molten salt) varies depending on the type of the molten salt to be used. However, the process temperature may be, for example, within a range of 350-550° C.

The chemically strengthening process may also be performed, for example, by immersing a glass substrate in a molten potassium nitrate salt at 350-550° C. for about 2 minutes-20 hours. From an economical and practical point of view, it is preferably performed at 350-500° C. for 1-10 hours.

According to the aforementioned configurations, a glass substrate with a surface on which a compression stress layer is formed can be obtained.

(Step S120)

Next, an antifouling layer 120 is formed on the rugged layer 130 that was formed at step S110.

The antifouling layer 120 may be configured of a resin including fluorine, as described above, e.g. the resin represented by formula (2) or formula (3).

A method of forming the antifouling layer 120 is not particularly limited. The antifouling layer 120 may be formed by using a dry method or a wet method.

In the dry method, a material configuring the antifouling layer 120 is deposited on the rugged layer 130 of the glass substrate 110. In the wet method, a liquid solution including the material configuring the antifouling layer 120 is applied on the rugged layer 130 of the glass substrate 110, and thereafter by drying the liquid solution the antifouling layer 120 is formed.

Note that before forming the antifouling layer 120, as necessary, a washing process or a surface preparation process may be performed for the rugged layer 130 of the glass substrate 110. Moreover, after forming the antifouling layer 120, in order to enhance adhesion strength of the antifouling layer 120, a heating process or a humidification process may be performed.

According to the aforementioned configurations, a first laminated body 100 having the aforementioned feature can be manufactured.

### Second Embodiment

Next, a second embodiment of the present invention will be described with reference to FIG. 4. FIG. 4 schematically illustrates a cross section of a laminated body according to the second embodiment of the present invention (in the following, referred to as a “second laminated body).

As illustrated in FIG. 4, the second laminated body 200 includes a substrate 210, an antifouling layer 220 and an intermediate layer 250 arranged between the substrate 210 and the antifouling layer 220.

The substrate 210 has a first surface 212 and a second surface 214. The intermediate layer 250 is arranged near the first surface 212.

The intermediate layer 250 is arranged in order to cause the second laminated body 200 to exhibit one additional function or two or more additional functions, such as a low reflection function, a low radiation function, a heat insulation function and/or the like. Alternatively, in the first manufacturing method, described as above, an undercoat layer (e.g. layer including silicon oxide) arranged on the rugged layer 130 for the surface preparation process before forming the antifouling layer 120 may be regarded as a type of an intermediate layer 250.

The intermediate layer 250 may be configured of a single layer or a plurality of layers. A material of the intermediate layer 250 is not particularly limited. The intermediate layer 250 may include an oxide layer, a nitride layer, an oxinitride layer and/or a metal layer.

For example, in the case where the intermediate layer 250 is an intermediate layer having a low reflection function, the intermediate layer 250 may be configured by alternately laminating at least one high refraction index layer and at least one low refraction index layer. Alternatively, the intermediate layer 250 may be configured by including an inclined film in which a refraction index varies continuously in the film. The refraction index of the high refraction index layer is preferably within 1.70 to 2.70, and the refraction index of the low refraction index layer is preferably within 1.30 to 1.55. For example, the intermediate layer 250 may have a four layers structure including, from a side near the substrate 210, a niobium oxide layer (or titanium oxide layer)/a silica layer/a niobium oxide layer (or titanium oxide layer)/a silica layer. The structure may include aluminum nitride or silicon nitride. The structure may include more than four layers in the structure. The structure is not limited to the aforementioned structures, and the layer configuration is not particularly limited.

In the case where the aforementioned low reflection intermediate layer is configured of a laminated body including at least one high refraction index layer and at least one low refraction index layer, a thickness of each high refraction index layer configuring the intermediate layer is preferably less than 90 nm. Moreover, the thickness of the high refraction index layer is more preferably less than 70 nm. The surface roughness Ra of the rugged layer 230 according to the embodiment falls within a range of 0.5 nm to 50 nm. In such a case, compared with the case of the surface roughness Ra of less than 0.5 nm, light is easily scattered after forming the intermediate layer, and a loss of a transmission factor or a haze is liable to occur. Accordingly, if the thickness of the high refraction index layer is reduced, an optical path length can be made shorter, the occurrence of a loss of a transmission factor or of a haze can be controlled against, and it is preferable. Particularly, as the surface roughness Ra increases, the aforementioned properties tend to become more notable. Thus, the surface roughness Ra of the rugged layer 230 falling within a range of 4 nm to 50 nm is effective, and the surface roughness Ra falling within a range of 7 nm to 30 nm is particularly effective.

In addition to the aforementioned structure, various layer structures are conceivable.

The second laminated body 200 has the rugged layer 230 including fluorine on the first surface 212 of the substrate 210. In other words, in the second laminated body 200, the rugged layer 230 including fluorine is arranged between the substrate 210 and the intermediate layer 250.

The intermediate layer 250 may have a rugged structure on a surface thereof following the surface structure of the rugged layer 230. Note that even if the intermediate layer 250 has a rugged structure, in the case where fluorine F is not included, the rugged structure can be distinguished from the rugged layer described in the present application.

The features of the rugged layer 230 including fluorine and the antifouling layer 220 are the same as the rugged layer 130 including fluorine and the antifouling layer 120 in the aforementioned first laminated body 100, respectively.

Therefore, also in the second laminated body 200, the same effect as the first laminated body 100 can be obtained. That is, in the second laminated body 200, the antifouling layer 220 is not liable to be degraded or exfoliated under an actual usage environment, and exhibits an excellent durability.

Note that in the second laminated body 200, the rugged layer 230 is arranged not immediately below the antifouling layer 220, but at a position separated from the antifouling layer 220. However, the intermediate layer 250 is typically configured of a relatively thin film, e.g. a film with a thickness of 1 nm to 500 nm. Then, also in such a configuration of the second laminated body 200, the same effect as the first laminated body 100 can be obtained.

(Manufacturing Method of the Second Laminated Body 200)

Next, with reference to FIG. 5, a manufacturing method of the second laminated body 200 will be described.

FIG. 5 schematically depicts an example of the manufacturing method of the second laminated body (in the following, referred to as a “second manufacturing method”). As illustrated in FIG. 5, the second manufacturing method includes

a rugged layer formation step for forming a rugged layer including fluorine on a substrate (step S210);

an intermediate layer formation step for forming an intermediate layer on the rugged layer (step S220); and

an antifouling layer formation step for forming an antifouling layer on the intermediate layer (step S230).

Among the aforementioned steps, step S210 and step S230 are the same as step S110 and step S120 illustrated in the first manufacturing method, respectively. Thus, in the following, step S220 will be mainly explained. Moreover, in the following explanation, in order to make clear the explanation, when illustrating the respective members, the reference numerals used in FIG. 4 will be used.

(Step S220)

In step S220, the intermediate layer 250 is formed on the substrate 210 having the rugged layer 230 including fluorine that was obtained at step S210.

A method of forming the intermediate layer 250 is not particularly limited. The intermediate layer 250 may be deposited by, for example, a vapor-deposition method such as an electron beam vapor-deposition or a resistance heating, a CVD method, a plasma CVD method, a sputtering method, a coating method, or the like. The intermediate layer 250 may be formed by a surface reformulation such as an ion gun method, or a plasma cleaning method.

Afterwards, at step S230, the antifouling layer 220 is formed on the intermediate layer 250, and thereby the second laminated body 200 having the configuration illustrated in FIG. 4 can be manufactured.

### Third Embodiment

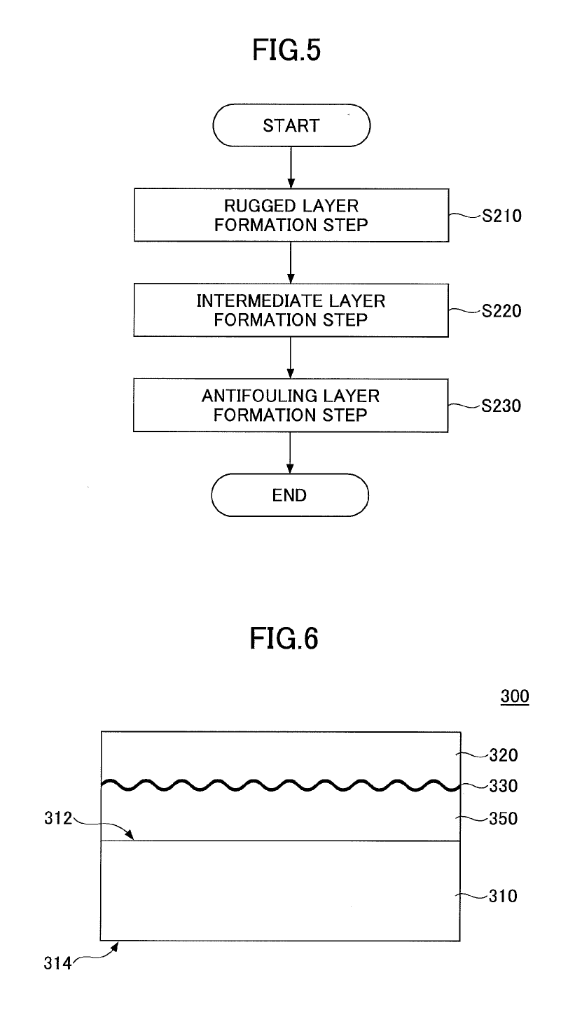

Next, a third embodiment of the present invention will be described with reference to FIG. 6. FIG. 6 schematically illustrates a cross-section of a laminated body according to the third embodiment of the present invention (in the following, referred to as a “third laminated body”).

As illustrated in FIG. 6, the third laminated body 300 includes a substrate 310, an antifouling layer 320 and an intermediate layer 350 arranged between the substrate 310 and the antifouling layer 320.

The substrate 310 has a first surface 312 and a second surface 314. The intermediate layer 350 is arranged near the first surface 312. As described in the second embodiment, the intermediate layer 350 is arranged in order to cause the third laminated body 300 to exhibit one additional function or two or more additional functions. Moreover, the intermediate layer 350 may be configured of a single layer, or may be configured of a plurality of layers.

Note that in the third laminated body 300, an uppermost layer of the intermediate layer 350, i.e. a layer facing the antifouling layer includes silicon.

In the third laminated body 300, different from the second laminated body 200, an upper surface of the intermediate layer 350 has a rugged layer 330 including fluorine. In other words, in the third laminated body 300, the rugged layer 330 including fluorine is arranged between the intermediate layer 350 and the antifouling layer 320.

The features of the rugged layer 330 including fluorine and the antifouling layer 320 are the same as the rugged layers 130, 230 including fluorine and the antifouling layers 120, 220 in the aforementioned first laminated body 100 and the second laminated body 200, respectively.

Therefore, also in the third laminated body 300, the same effect as the first laminated body 100 or the second laminated body 200 can be obtained. That is, the antifouling layer 320 is not liable to be degraded or exfoliated under an actual usage environment, and exhibits an excellent durability.

Note that in the example of the third laminated body 300 illustrated in FIG. 6, one rugged layer 330 including fluorine is arranged between the intermediate layer 350 and the antifouling layer 320. However, the laminated body may include a plurality of rugged layers including fluorine. In such a case, for example, one rugged layer is arranged between the substrate and the intermediate layer, and another rugged layer may be arranged between the intermediate layer and the antifouling layer.

(Manufacturing Method of the Third Laminated Body 300)

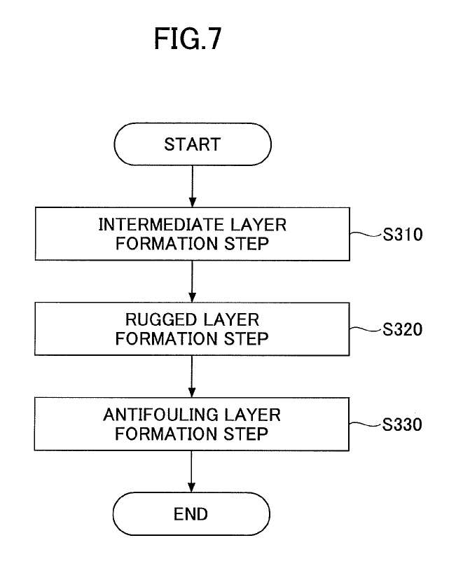

Next, with reference to FIG. 7, a manufacturing method of the third laminated body 300 will be described.

FIG. 7 schematically illustrates a flow of the manufacturing method of the third laminated body 300 (in the following, referred to as a “third manufacturing method”). As illustrated in FIG. 7, the third manufacturing method includes

an intermediate layer formation step for forming an intermediate layer on a substrate (step S310);

a rugged layer formation step for forming a rugged layer including fluorine on the intermediate layer (step S320); and

an antifouling layer formation step for forming an antifouling layer on the rugged layer (step S330).

Among the aforementioned steps, step S310 and step S330 are the same as step S220 and step S230 illustrated in the second manufacturing method, respectively. Thus, in the following, step S320 will be mainly explained. Moreover, in the following explanation, in order to make clear the explanation, when illustrating the respective members, the reference numerals used in FIG. 6 will be used.

(Step S320)

In step S320, the rugged layer 330 is formed above the substrate 310 having the intermediate layer 350 that was obtained at step S310.

A method of forming the rugged layer 330 is not particularly limited. For example, the rugged layer 330 may be formed by using an etching process, as illustrated in the process at step S110 in the first manufacturing method.

Note that at this step, a processed body subjected to the etching process is the intermediate layer 350, different from the first manufacturing method. Thus, the uppermost layer of the intermediate layer 350 is required to include silicon (Si). Otherwise, the aforementioned feature, i.e. a ratio of an atomic concentration (atom %) of fluorine obtained from the peak of the binding energy of F1s of fluorine to an atomic concentration (atom %) of silicon obtained from a peak of a binding energy of Si2p of silicon, i.e. F1s/Si2p, falling within a range of 0.003 to 100, cannot be obtained.

An etching system may be a dry etching system, or may be a wet etching system. A method of the etching is not particularly limited, but, for example, in the case of the dry etching system, any of a CVD method, a plasma CVD method, a reactive ion etching (RIE) method, an inductively coupled plasma (ICP) method, a reverse sputtering method, an ion milling method, and a laser ion source (LIS) method, or a combination thereof may be employed.

Afterwards, at step S330, the antifouling layer 320 is formed on the rugged layer 330, and thereby the third laminated body 300 having the configuration illustrated in FIG. 6 can be manufactured.

### EXAMPLES

Next, practical examples according to the present invention will be described. The following examples 1 to 14 are practical examples, and examples 21 to 26 are comparative examples.

### Example 1

With the following method, the first laminated body provided with the configuration as illustrated in FIG. 1 was manufactured. For the substrate, a glass substrate with a thickness of 0.7 mm (aluminosilicate glass) was used.

(Forming a Rugged Layer)

One surface of the glass substrate was subjected to an etching process with a HF gas, to form a rugged layer.

For the etching process, the device 1 illustrated in FIG. 3 was used. In the device 1, a mixed gas including a HF gas and a nitrogen gas (HF concentration was 0.4 vol %) was supplied to the first slit 15 at the central portion, and a nitrogen gas was supplied to the second slit 20 arranged outside the first slit 15. An amount of exhaust from the outermost third slit 25 was twice the total amount of supply. A glass substrate was conveyed in a state of being heated at 580° C. An etching process time was 10 seconds.

After the etching process, the glass substrate was washed with pure water to remove residues on a surface.

Next, by using a scanning probe microscope (SPI3800N by SII Nano Technology Inc.), a surface roughness Ra of the rugged layer was measured. The measurement of the surface roughness Ra was performed for a region of 2 μm squared of the rugged layer, and data of 1024×1024 was obtained. As a result of measurement, the surface roughness Ra of the rugged layer was 0.5 nm.

Moreover, the binding energies of F1s and Si2p in the rugged layer were evaluated. For the evaluation of the binding energy, an X-ray photoelectronic spectrometer (PHI1500 VersaProbe, by Ulvac-phi, Inc.) was used. For the measurement of F1s, an energy range was 679 eV to 694 eV, a step in energy was 0.1 eV, and a total number of evaluation times was 200. For the measurement of Si2p, an energy range was 96 eV to 111 eV, a step in energy was 0.1 eV, and a total number of evaluation times was 50. As a result of evaluation, a peak position of the binding energy of F1s in the rugged layer was 685.0 eV. Moreover, a ratio of an atomic concentration (atom %) of fluorine F1s to an atomic concentration (atom %) of silicon Si2p (in the following, referred to as an “F1s/Si2p ratio”) was 0.08.

Next, a chemically strengthening process was performed for the glass substrate having the rugged layer on a surface thereof. The chemically strengthening process was performed by immersing the glass substrate which has been subjected to the etching process in a molten salt including potassium nitrate of 90% to 100% at 435° C. for two hours.

Note that it was confirmed that a property of the rugged layer was unchanged between before and after the chemically strengthening process.

Using the glass substrate after the chemically strengthening process, Martens hardness was measured. For the measurement, Picodentor HM 500 (Fisher Instruments K.K.) was used, and based on ISO 14577, the measurement was performed from the rugged layer side. For an indenter, a Vickers indenter was used.

As a result of measurement, the Martens hardness was 3710 N/mm².

(Formation of Antifouling Layer)

Next, the antifouling layer was formed on the rugged layer of the glass substrate.

The antifouling layer was the resin indicated by the aforementioned formula (2), and was deposited by using a deposition method with a compound in a liquid state as a deposition source. Note that an undercoat layer was not arranged before depositing the antifouling layer, and the antifouling layer was directly deposited on an upper part of the rugged layer.

A thickness of the antifouling layer was aimed to be a thickness at which an F value is 2.8 when deposited on a typical flat substrate.

According to the above described processes, the laminated body (a laminated body according to Example 1) was manufactured.

By using the same measurement method as in the measurement for the rugged layer, the binding energy of F1s for the obtained antifouling layer was evaluated. As a result, a peak of the binding energy of F1s was at 688.7 eV.

Moreover, by using the aforementioned formula (1), an F value was evaluated. For a fluorescent X-ray measurement apparatus, ZSX Primus II (by Rigaku Corporation, output was Rh 50 kV-72 mA) was used. Note that the B-value in the formula (1) was obtained by measurement for an aluminosilicate glass plate that practically did not include fluorine, and the C-value in the formula (1) was obtained by measurement for an aluminosilicate glass plate including fluorine of 2 wt %. The obtained F-value was 2.9.

### Example 2

By using the same method as in Example 1, a laminated body (laminated body according to Example 2) was manufactured.

In Example 2, the chemically strengthening process was not performed for the glass substrate.

Moreover, in Example 2, the laminated body had the aforementioned configuration illustrated in FIG. 4. The intermediate layer was a silica layer with a thickness of 20 nm. The silica layer functioned as an undercoat layer for an antifouling layer. The silica layer was deposited with Si as a target by a sputtering method. A flow rate ratio of introduced gases was 1:2 (argon:oxygen). A power density was 1 W/cm².

Moreover, in Example 2, a glass substrate was subjected to an etching process with an etching condition different from that in the case of Example 1, and a rugged layer with a surface roughness Ra of 1 nm was formed. A thickness of the antifouling layer was aimed to be a thickness at which an F value is 1.2 when deposited on a typical flat substrate. Other manufacturing conditions were the same as those in the case of Example 1.

### Example 3

By using the same method as in Example 2, a laminated body (laminated body according to Example 3) was manufactured.

In Example 3, a glass substrate was subjected to an etching process with an etching condition different from the case of Example 2, and a rugged layer with a surface roughness Ra of 4 nm was formed. A thickness of an antifouling layer was aimed to be a thickness at which an F value is 1.8 when depositing on a typical flat substrate. Other manufacturing conditions were the same as those in the case of Example 1.

### Example 4

By using the same method as in Example 1, a laminated body (laminated body according to Example 4) was manufactured.

In Example 4, a glass substrate was subjected to an etching process with an etching condition different from the case of Example 1, and a rugged layer with a surface roughness Ra of 6 nm was formed. A thickness of an antifouling layer was aimed to be a thickness at which an F value is 2.8 when depositing on a typical flat substrate. Other manufacturing conditions were the same as those in the case of Example 1.

### Example 5

By using the same method as in Example 2, a laminated body (laminated body according to Example 5) was manufactured.

In Example 5, the chemically strengthening process was performed for a glass substrate after forming a rugged layer.

Moreover, in Example 5, the glass substrate was subjected to an etching process with an etching condition different from the case of Example 2, and a rugged layer with a surface roughness Ra of 6 nm was formed. Furthermore, a thickness of an intermediate layer (silica layer) was 10 nm. A thickness of an antifouling layer was aimed to be a thickness at which an F value is 2.5 when depositing on a typical flat substrate. Other manufacturing conditions were the same as those in the case of Example 2.

### Example 6

By using the same method as in Example 5, a laminated body (laminated body according to Example 6) was manufactured.

In Example 6, a glass substrate was subjected to an etching process with an etching condition different from the case of Example 5, and a rugged layer with a surface roughness Ra of 10 nm was formed. A silica layer was deposited by using an electron beam evaporation method with a silica target.

Furthermore, an antifouling layer was deposited using a pellet shape deposition source obtained by impregnating a metallic porous body (steel wool) with a solution obtained by diluting a compound including fluorine with a solvent and putting the steel wool in a copper hearth. A thickness of the antifouling layer was aimed to be a thickness at which an F value is 1.5 when depositing on a typical flat substrate. Other manufacturing conditions were the same as those in the case of Example 2.

### Example 7

By using the same method as in Example 6, a laminated body (laminated body according to Example 7) was manufactured. In Example 7, a glass substrate was subjected to an etching process with an etching condition different from the case of Example 6, and a rugged layer with a surface roughness Ra of 11 nm was formed. Moreover, a thickness of an intermediate layer (silica layer) was 20 nm. The silica layer was deposited by using an electron beam evaporation method with a silica target. After forming the intermediate layer, a haze value of the glass substrate was measured. For the measurement, a haze meter (HZ-2: by Suga Test Instruments Co., Ltd.) was used, and the measurement was performed based on JIS K7361-1. Furthermore, a C light source was used for a light source.

Moreover, as a material for the antifouling layer, a compound that was represented by the aforementioned formula (3) was used. A thickness of the antifouling layer was aimed to be a thickness at which an F value is 1.4 when depositing on a typical flat substrate. Other manufacturing conditions were the same as those in the case of Example 6.

### Example 8

By using the same method as in Example 6, a laminated body (laminated body according to Example 8) was manufactured. In Example 8, a glass substrate was subjected to an etching process with an etching condition different from the case of Example 6, and a rugged layer with a surface roughness Ra of 6 nm was formed. Moreover, in Example 8, the chemically strengthening process was not performed for the glass substrate.

Furthermore, after depositing an antifouling layer, the laminated body was maintained for 10 hours in a humid environment of 40% to 60%, and washed by wiping with a Bemcot clean EA-8 permeated with pure water. A thickness of the antifouling layer was aimed to be a thickness at which an F value is 0.9 when depositing on a typical flat substrate. Other manufacturing conditions were the same as those in the case of Example 6.

### Example 9

By using the same method as in Example 5, a laminated body (laminated body according to Example 9) was manufactured. In Example 9, as an intermediate layer, a layer having a four layered structure of a niobium oxide (thickness was 14 nm)/a silica layer (thickness was 31 nm)/a niobium oxide layer (thickness was 109 nm)/a silica layer (thickness was 97 nm) was formed.

The niobium oxide layer was deposited using a sputtering method with a Nb target. A deposition atmosphere was a mixed gas atmosphere of argon and oxygen. A mixing ratio of argon:oxygen was 1:2. A power density upon deposition was 1 W/cm². The silica layer was deposited using a sputtering method with a Si target. A deposition pressure was 3 mTorr for both layers. A thickness of the antifouling layer was aimed at a thickness, with which an F value was 0.9 when depositing on a typical flat substrate.

Other manufacturing conditions were the same as those in the case of Example 5.

### Example 10

By using the same method as in Example 9, a laminated body (laminated body according to Example 10) was manufactured. In Example 10, as an intermediate layer, a layer having a four layered structure of a niobium oxide (thickness was 20 nm)/a silica layer (thickness was 40 nm)/a niobium oxide layer (thickness was 28 nm)/a silica layer (thickness was 105 nm) was formed. Other manufacturing conditions were the same as those in the case of Example 9.

### Example 11

By using the same method as in Example 9, a laminated body (laminated body according to Example 11) was manufactured. In Example 11, a glass substrate was subjected to an etching process with an etching condition different from the case of Example 9, and a rugged layer with a surface roughness Ra of 10 nm was formed.

Other manufacturing conditions were the same as those in the case of Example 9.

### Example 12

By using the same method as in Example 10, a laminated body (laminated body according to Example 12) was manufactured. In Example 12, a glass substrate was subjected to an etching process with an etching condition different from the case of Example 10, and a rugged layer with a surface roughness Ra of 10 nm was formed. Other manufacturing conditions were the same as those in the case of Example 10.

From results of Example 10 and Example 12, when a thickness of a high refraction index layer was less than 90 nm, an effect of controlling against occurrence of haze was found to be present, and the effect was found to be greater as the surface roughness Ra increased.

### Example 13

In Example 13, a third laminated body having the aforementioned configuration illustrated in FIG. 6 was manufactured. For a substrate, a glass substrate (aluminosilicate glass) with a thickness of 0.7 mm was used. The chemically strengthening process was not performed for the glass substrate.

Next, an intermediate layer was deposited on the glass substrate. The intermediate layer with the four layered structure, which was the same as the intermediate layer in Example 9, was employed. The respective layers were deposited using the same method as the deposition method for the intermediate layer in Example 9.

Next, an etching process was performed for the glass substrate including the intermediate layer from the intermediate layer side. A method of the etching process was the same as that in the case of Example 1. Note that after the etching process, the glass substrate was not washed with water.

According to the aforementioned process, a rugged layer was formed on the intermediate layer. A surface roughness Ra of the rugged layer was 0.7 nm.

Next, an antifouling layer was formed on the rugged layer. A thickness of the antifouling layer was aimed to be a thickness at which an F value is 1.4 when depositing on a typical flat substrate.

Thus, the laminated body according to Example 13 was manufactured.

### Example 14

By using the same method as in Example 6, a laminated body (laminated body according to Example 14) was manufactured. In Example 14, a glass substrate was subjected to an etching process with an etching condition different from the case of Example 6, and a rugged layer with a surface roughness Ra of 20 nm was formed. Other manufacturing conditions were the same as those in the case of Example 6.

TABLE 1, in the following, shows the configurations of the laminated body, formation conditions of the respective parts and the like, according to respective examples as a whole.

TABLE 1

| | | | | | | | | | | haze value |
|---|---|---|---|---|---|---|---|---|---|---|
| | | substrate | | rugged | | | | | | after |
| | | | chemically | layer | Martens | | antifouling layer | | | forming |
| | config- | | strengthening | Ra | hardness | | | deposition | post | intermediate |
| example | uration | type | process | (nm) | (N/mm²) | intermediate layer | material | source | process | layer |
| 1 | FIG. 1 | glass | yes | 0.5 | 3710 | — | formula | liquid | none | — |
| | | | | | | | (2) | | | |
| 2 | FIG. 4 | glass | no | 1 | — | silica layer of 20 nm | formula | liquid | none | — |
| | | | | | | | (2) | | | |
| 3 | FIG. 4 | glass | no | 4 | 3620 | silica layer of 20 nm | formula | liquid | none | — |
| | | | | | | | (2) | | | |
| 4 | FIG. 1 | glass | yes | 6 | 3340 | — | formula | liquid | none | — |
| | | | | | | | (2) | | | |
| 5 | FIG. 4 | glass | yes | 6 | — | silica layer of 10 nm | formula | liquid | none | — |
| | | | | | | | (2) | | | |
| 6 | FIG. 4 | glass | yes | 10 | 2620 | silica layer of 10 nm | formula | pellet | none | — |
| | | | | | | (electron beam | (2) | | | |
| | | | | | | deposition) | | | | |
| 7 | FIG. 4 | glass | yes | 11 | — | silica layer of 20 nm | formula | pellet | none | — |
| | | | | | | (electron beam | (2) | | | |
| | | | | | | deposition) | | | | |
| 8 | FIG. 4 | glass | no | 6 | — | silica layer of 10 nm | formula | pellet | maintain | — |
| | | | | | | (electron beam | (2) | | in humid | |
| | | | | | | deposition) | | | 10 hours + | |
| | | | | | | | | | wiping | |
| 9 | FIG. 4 | glass | yes | 6 | 4020 | niobium oxide/silica/ | formula | liquid | none | 0.10 |
| | | | | | | niobium oxide/silica | (2) | | | |
| 10 | FIG. 4 | glass | yes | 6 | — | niobium oxide/silica/ | formula | liquid | none | 0.07 |
| | | | | | | niobium oxide/silica | (2) | | | |
| 11 | FIG. 4 | glass | yes | 10 | 3810 | niobium oxide/silica/ | formula | liquid | none | 0.78 |
| | | | | | | niobium oxide/silica | (2) | | | |
| 12 | FIG. 4 | glass | yes | 10 | — | niobium oxide/silica/ | formula | liquid | none | 0.29 |
| | | | | | | niobium oxide/silica | (2) | | | |
| 13 | FIG. 6 | glass | no | 0.7 | 4170 | niobium oxide/silica/ | formula | liquid | none | — |
| | | | | | | niobium oxide/silica | (2) | | | |
| 14 | FIG. 4 | glass | yes | 20 | 2208 | silica layer of 10 nm | formula | pellet | none | 0.21 |
| | | | | | | (electron beam | (2) | | | |
| | | | | | | deposition) | | | | |

Note that in each example, the Martens hardness was measured before forming the antifouling layer.

### Example 21

By using the same method as in Example 1, a laminated body (laminated body according to Example 21) was manufactured. In Example 21, the chemically strengthening process was not performed for the glass substrate. Moreover, a process of forming a rugged layer on a surface of the glass substrate was not performed. That is, an antifouling layer was formed directly on the surface of the glass substrate. A formation condition for the antifouling layer was the same as that of Example 1.

### Example 22

By using the same method as in Example 21, a laminated body (laminated body according to Example 22) was manufactured. In Example 22, a silica layer with a thickness of 10 nm was formed on a surface of a glass substrate as an undercoat layer before forming an antifouling layer. The silica layer was deposited using an electron beam deposition method with a silica target.

Moreover, in Example 22, a formation condition for the antifouling layer was the same as that of Example 6. Other manufacturing conditions were the same as those in the case of Example 21.

### Example 23

By using the same method as in Example 22, a laminated body (laminated body according to Example 23) was manufactured. In Example 23, the chemically strengthening process was performed for the glass substrate before forming an intermediate layer. Moreover, a thickness of an undercoat layer (silica layer) was 20 nm.

Moreover, in Example 23, for a material of an antifouling layer, a compound represented by the aforementioned formula (3) was used. A formation condition for the antifouling layer was the same as that of Example 7. Other manufacturing conditions were the same as those in the case of Example 22.

### Example 24

By using the same method as in Example 22, a laminated body (laminated body according to Example 24) was manufactured. In Example 24, formation conditions for an antifouling layer and a post processing were the same as those in the case of Example 6. Other manufacturing conditions were the same as those in the case of Example 22.

### Example 25

By using the same method as in Example 13, a laminated body (laminated body according to Example 25) was manufactured. In Example 25, a process of forming a rugged layer in an upper portion of an intermediate layer was not performed. That is, an antifouling layer was formed directly on the upper portion of the intermediate layer, and thereby the laminated body was configured. The configuration of the antifouling layer and a deposition condition were the same as those in the case of Example 9.

### Example 26

By using the same method as in Example 1, a laminated body (laminated body according to Example 26) was manufactured. In Example 26, an etching process was performed for a glass substrate under an etching condition different from that in the case of Example 1, and a rugged layer with a surface roughness Ra of 0.2 nm was formed. A formation condition for an antifouling layer was the same as that in the case of Example 1.

TABLE 2, in the following, shows the configurations of the laminated body, formation conditions of the respective parts and the like, according to examples 21 to 26 as a whole.

TABLE 2

| | | substrate | | | | | | | |
|---|---|---|---|---|---|---|---|---|---|
| | | | | chemically | Martens | | antifouling layer | | |
| | | | Ra | strengthening | hardness | | | deposition | post |
| example | configuration | type | (nm) | process | (N/mm²) | intermediate layer | material | source | process |
| 21 | substrate/antifouling | glass | 0.1 | no | 3820 | — | formula | liquid | none |
| | layer | | | | | | (2) | | |
| 22 | substrate/intermediate | glass | 0.1 | no | 4060 | silica layer of 10 nm | formula | pellet | none |
| | layer/antifouling layer | | | | | (electron beam | (2) | | |
| | | | | | | deposition) | | | |
| 23 | substrate/intermediate | glass | 0.1 | yes | — | silica layer of 20 nm | formula | pellet | none |
| | layer/antifouling layer | | | | | (electron beam | (2) | | |
| | | | | | | deposition) | | | |
| 24 | substrate/intermediate | glass | 0.2 | no | — | silica layer of 10 nm | formula | pellet | maintain |
| | layer/antifouling layer | | | | | (electron beam | (2) | | in humid |
| | | | | | | deposition) | | | 10 hours + |
| | | | | | | | | | wiping |
| 25 | substrate/intermediate | glass | 0.6 | no | 4300 | niobium oxide/silica/ | formula | liquid | none |
| | layer/antifouling layer | | | | | niobium oxide/silica | (2) | | |
| 26 | substrate/antifouling | glass | 0.2 | yes | — | — | formula | liquid | none |
| | layer | | | | | | (2) | | |

(Durability Evaluation Test)

A durability evaluation test was performed for the respective laminated bodies manufactured as above. The durability evaluation test was performed as follows.

First, using a cloth soaked with ethanol (Bemcot clean EA-8 by Asahi Kasei Corporation), a surface of an antifouling layer of a laminated body was scrubbed strongly. More specifically, on the surface of the antifouling layer, the surface was scrubbed back and forth for 6 times in the longitudinal direction between one end portion and another end portion of the laminated body. Next, the reciprocating direction was rotated by 90°, and on the surface of the antifouling layer, the surface was scrubbed back and forth for 6 times in the transverse direction between one end portion and another end portion of the laminated body.

An initial F-value of the laminated body exhibited a difference between the configuration including the rugged layer (practical example) and the configuration without the rugged layer (comparative example). That is, when the deposition condition for the antifouling layer was the same, the F-value for the configuration including the rugged layer was greater than the F-value for the configuration without the rugged layer. Comparing the F-values after the durability test, the F-value for the configuration including the rugged layer was greater, i.e. a remaining amount was greater. In such a durability evaluation test, it can be said that the greater the remaining amount is, the higher the durability is.

Moreover, a residual ratio (%) of the antifouling layer was evaluated after the durability test. The residual ratio (%) is expressed by the following formula (4):

Residual ratio (%)=(F-value of antifouling layer after scrub by cloth)/(initial F-value of antifouling layer). formula (4)

Note that the respective F-values of the numerator and the denominator in formula (4) can be obtained from aforementioned formula (1).

In such a durability evaluation test, it can be said that the greater the remaining amount and/or the residual ratio (%) is, the higher the durability of the antifouling layer is.

TABLE 3, in the following, shows results of the durability evaluation test obtained for the respective laminated body as a whole.

TABLE 3

| | | | antifouling | | after durability | | |
|---|---|---|---|---|---|---|---|
| | rugged layer | | layer | | evaluation test | | |
| | peak of | | peak of | | | | |
| | binding | | binding | | | | |
| | energy | F1s/ | energy | | | residual | |
| ex- | of F1s | Si2p | of F1s | F- | F- | ratio | |
| ample | (eV) | ratio | (eV) | value | value | (%) | result |
| 1 | 685.0 | 0.08 | 688.7 | 2.9 | 1.7 | 59 | excellent |
| 2 | 685.1 | 0.09 | 688.7 | 1.5 | 1.2 | 79 | excellent |
| 3 | 685.2 | 0.13 | 688.7 | 2.0 | 1.4 | 70 | excellent |
| 4 | 685.4 | 0.15 | 688.8 | 3.0 | 2.0 | 67 | excellent |
| 5 | 685.4 | 0.15 | 688.8 | 3.2 | 2.3 | 73 | excellent |
| 6 | 685.7 | 0.21 | 688.7 | 1.8 | 1.4 | 77 | excellent |
| 7 | 686.0 | 0.22 | 688.7 | 1.8 | 1.7 | 95 | excellent |
| 8 | 685.4 | 0.16 | 688.7 | 1.6 | 0.9 | 58 | excellent |
| 9 | 685.2 | 0.13 | 688.7 | 1.9 | 1.3 | 66 | excellent |
| 11 | 685.5 | 0.16 | 688.7 | 2.0 | 1.5 | 75 | excellent |
| 13 | 687.0 | 0.003 | 688.7 | 1.7 | 1.0 | 60 | excellent |
| 14 | 686.1 | 0.26 | 688.8 | 4.9 | 4.9 | 100 | excellent |
| 21 | — | 0 | 688.6 | 2.8 | 0.5 | 19 | insufficient |
| 22 | — | 0 | 688.7 | 1.5 | 0.6 | 40 | insufficient |
| 23 | — | 0 | 688.6 | 1.4 | 0.5 | 39 | insufficient |
| 24 | — | 0 | 688.7 | 0.9 | 0.5 | 53 | insufficient |
| 25 | — | 0 | 688.7 | 1.8 | 0.6 | 35 | insufficient |
| 26 | 686.0 | 0.21 | 688.6 | 1.4 | 0.6 | 43 | insufficient |

Note that TABLE 3 also shows a peak of binding energy of F1s and an F1s/Si2p ratio of the rugged layer, and a peak of binding energy of F1s and an initial F-value of the antifouling layer for each laminated body.

From the results, the remaining amount and the residual ratio (%) of the antifouling layer after the durability evaluation test are found to be relatively great for the laminated bodies according to Examples 1 to 14. Particularly among them, Examples 7 and 12 in which the surface roughness Ra of the rugged layers are 11 nm or more, show that the residual ratios after durability evaluation test were 90% or more, and were found to exhibit excellent results. The laminated bodies according to Examples 21 to 25 show that the remaining amounts of the antifouling layer obtained by the durability evaluation test were less than 0.9 and that the residual ratio (%) was 53% at a maximum, and were found to be insufficient in durability.

In this way, it was found that in the laminated bodies according to Examples 1 to 14, durability of the antifouling layer is significantly enhanced. In Example 26, in which the surface roughness Ra is 0.2 nm, the residual ratio after the durability evaluation test is 43%, and the result is not excellent. It was found that when the surface roughness Ra is too small, the residual ratio becomes low.

Note that even in the case of performing a similar durability evaluation test using a dry cloth, or a cloth soaked with pure water or a fluorinated organic solvent such as AK225, the same effect can be obtained.

### REFERENCE SIGNS LIST

1 device
10 injector
15,20,25 slit
50 conveying means
100 first laminated body
110 substrate
112 first surface
114 second surface
120 antifouling layer
130 rugged layer
132 distribution region of fluorine
200 second laminated body
210 substrate
212 first surface
214 second surface
220 antifouling layer
230 rugged layer
250 intermediate layer
300 third laminated body
310 substrate
312 first surface
314 second surface
320 antifouling layer
330 rugged layer
350 intermediate layer

What is claimed is:

1. A laminated body comprising, in this order:
a substrate provided with a first surface;
a rugged layer including fluorine; and
an antifouling layer,
wherein the rugged layer has an arithmetic average surface roughness Ra that falls within a range from 0.05 nm to 50 nm,
wherein a peak of a binding energy of F1s of fluorine in the rugged layer falls within a range of greater than or equal to 684 eV and less than or equal to 687.5 eV, a ratio of an atomic concentration (atm %) of fluorine obtained from the peak of the binding energy of F1s of fluorine to an atomic concentration (atom %) of silicon obtained from a peak of a binding energy of Si2p of silicon, i.e. F1s/Si2p, falls within a range from 0.003 to 100,
wherein a peak of a binding energy of F1s of fluorine in the antifouling layer falls within a range of greater than 687.5 eV and less than or equal to 691 eV, and
wherein an F-value expressed by (A−B)/(C−B) is greater than or equal to 0.1,
where “A” is an F-Kα line strength of the laminated body measured from the antifouling layer side by a fluorescent X-ray measurement device, “B” is an F-Kα line strength of a glass plate that practically does not include fluorine measured by the fluorescent X-ray measurement device, and “C” is an F-Kα line strength of an aluminosilicate glass plate including fluorine of 2 wt % measured by the fluorescent X-ray measurement device.

2. The laminated body according to claim 1, further comprising:
an intermediate layer between the substrate and the antifouling layer.

3. The laminated body according to claim 2,
wherein the intermediate layer is configured by alternately laminating a high refraction index layer or two or more high refraction index layers having a refraction index that falls within a range of 1.70 to 2.70 and a low refraction index layer or two or more low refraction index layers having a refraction index that falls within a range of 1.30 to 1.55.

4. The laminated body according to claim 3,
wherein a thickness of each high refraction index layer configuring the intermediate layer is less than 90 nm.

5. The laminated body according to claim 4,
wherein the thickness of each high refraction index layer configuring the intermediate layer is less than 70 nm.

6. The laminated body according to claim 4,
wherein the rugged layer has an arithmetic average surface roughness Ra that falls within a range from 4 nm to 50 nm.

7. The laminated body according to claim 6,
wherein the rugged layer has an arithmetic average surface roughness Ra that falls within a range from 7 nm to 30 nm.

8. The laminated body according to claim 2,
wherein the intermediate layer includes an inclined film in which a refraction index varies continuously in the film.

9. The laminated body according to claim 2,
wherein the intermediate layer is at least one of an oxide layer, a nitride layer, an oxinitride layer and a metal layer.

10. The laminated body according to claim 9,
wherein the rugged layer is provided immediately above the first surface of the substrate.

11. The laminated body according to claim 10,
wherein the intermediate layer is provided with a layer including silicon on a surface of the intermediate layer that faces the antifouling layer, and
wherein the intermediate layer is configured of a single layer or two or more layers.

12. The laminated body according to claim 1,
wherein the rugged layer has an arithmetic average surface roughness Ra that falls within a range from 4 nm to 50 nm.

13. The laminated body according to claim 12,
wherein the rugged layer has an arithmetic average surface roughness Ra that falls within a range from 11 nm to 30 nm.

14. The laminated body according to claim 11,
wherein the rugged layer has an arithmetic average surface roughness Ra that falls within a range from 4 nm to 50 nm.
